(19) United States
(12) Patent Application Publication
(10) Pub. No.: US 2024/0379483 A1
(43) Pub. Date: Nov. 14, 2024

(54) HEATER STRUCTURE, MULTILAYER STRUCTURE, PROCESSING APPARATUS AND METHOD OF MANUFACTURING SEMICONDUCTOR DEVICE

(71) Applicant: KOKUSAI ELECTRIC CORPORATION, Tokyo (JP)

(72) Inventor: Shuhei SAIDO, Toyama-shi (JP)

(73) Assignee: KOKUSAI ELECTRIC CORPORATION, Tokyo (JP)

(21) Appl. No.: 18/777,840

(22) Filed: Jul. 19, 2024

Related U.S. Application Data
(63) Continuation of application No. PCT/JP2022/003545, filed on Jan. 31, 2022.

(51) Int. Cl. H01L 23/34; H01L 21/67

(52) U.S. Cl. CPC H01L 23/345; H01L 21/67098

(57) ABSTRACT

It is possible to improve an energy saving efficiency of an apparatus. There is provided a technique using a heater structure that includes: a heat insulating structure provided with a heat generator configured to heat an inside of a reaction tube; and a multilayer assembly located outside the heat insulating structure and provided with a plurality of spaces therein, wherein the multilayer assembly comprises a plurality of heat insulators arranged along a direction extending outward from the heat insulating structure, the plurality of spaces are provided between the plurality of heat insulators, respectively, and an amount of a heat dissipated from the multilayer assembly is variable in accordance with a thermal conductivity of each of the spaces and a thermal emissivity of each of the heat insulators.

### CROSS-REFERENCE TO RELATED PATENT APPLICATION

This application is a bypass continuation application of PCT International Application No. PCT/JP2022/003545, filed on Jan. 31, 2022, in the WIPO, the entire contents of which are hereby incorporated by reference.

### BACKGROUND

### 1. Field

The present disclosure relates to a heater structure, a multilayer structure, a processing apparatus and a method of manufacturing a semiconductor device.

### 2. Related Art

According to some related arts, as a part of a manufacturing process of a semiconductor device, a process of forming a film on a substrate may be performed. Recently, it is preferable to apply an environmental adaptation not only to a semiconductor but also to a factory related thereto. For example, it is preferable to apply an energy saving configuration to facilities such as apparatuses in the factory. In particular, in an apparatus according to some related arts, a large amount of power is consumed when a substrate is processed. Thereby, it is preferable to further improve the energy saving efficiency.

### SUMMARY

According to the present disclosure, there is provided a technique capable of improving an energy saving efficiency of an apparatus.

According to an embodiment of the present disclosure, there is provided a technique using a heater structure that includes: a heat insulating structure provided with a heat generator configured to heat an inside of a reaction tube; and a multilayer assembly located outside the heat insulating structure and provided with a plurality of spaces therein, wherein the multilayer assembly comprises a plurality of heat insulators arranged along a direction extending outward from the heat insulating structure, the plurality of spaces are provided between the plurality of heat insulators, respectively, and an amount of a heat dissipated from the multilayer assembly is variable in accordance with a thermal conductivity of each of the spaces and a thermal emissivity of each of the heat insulators.

### BRIEF DESCRIPTION OF THE DRAWINGS

FIG. 1 is a diagram schematically illustrating a vertical cross-section of a substrate processing apparatus according to one or more embodiments of the present disclosure.

FIG. 2 is a diagram schematically illustrating a horizontal cross-section of a heater structure of the substrate processing apparatus according to the embodiments of the present disclosure.

FIG. 3 is a diagram schematically illustrating a detailed cross-section of a support of a heat insulator located on a side surface of the substrate processing apparatus shown in FIG. 1.

FIG. 4 is a diagram schematically illustrating a detailed cross-section of a support of a heat insulator located on an upper surface of the substrate processing apparatus shown in FIG. 1.

FIG. 5 is a block diagram schematically illustrating a configuration of a controller and related components of the substrate processing apparatus according to the embodiments of the present disclosure.

FIG. 6 is a diagram schematically illustrating a modified example of the heater structure of the substrate processing apparatus according to the embodiments of the present disclosure.

FIG. 7A is a diagram schematically illustrating a cross-section of a heater structure of the substrate processing apparatus according to an example of the embodiments of the present disclosure.

FIG. 7B is a diagram schematically illustrating a relationship between a distance from a center of a reaction tube and a temperature when a film forming process is performed using the substrate processing apparatus according to the example of the embodiments of the present disclosure.

FIG. 8A is a diagram schematically illustrating a cross-section of a heater structure of a substrate processing apparatus according to a comparative example.

FIG. 8B is a diagram schematically illustrating a relationship between a distance from a center of a reaction tube and a temperature when the film forming process is performed using the substrate processing apparatus according to the comparative example.

### DETAILED DESCRIPTION

### Embodiments of Present Disclosure

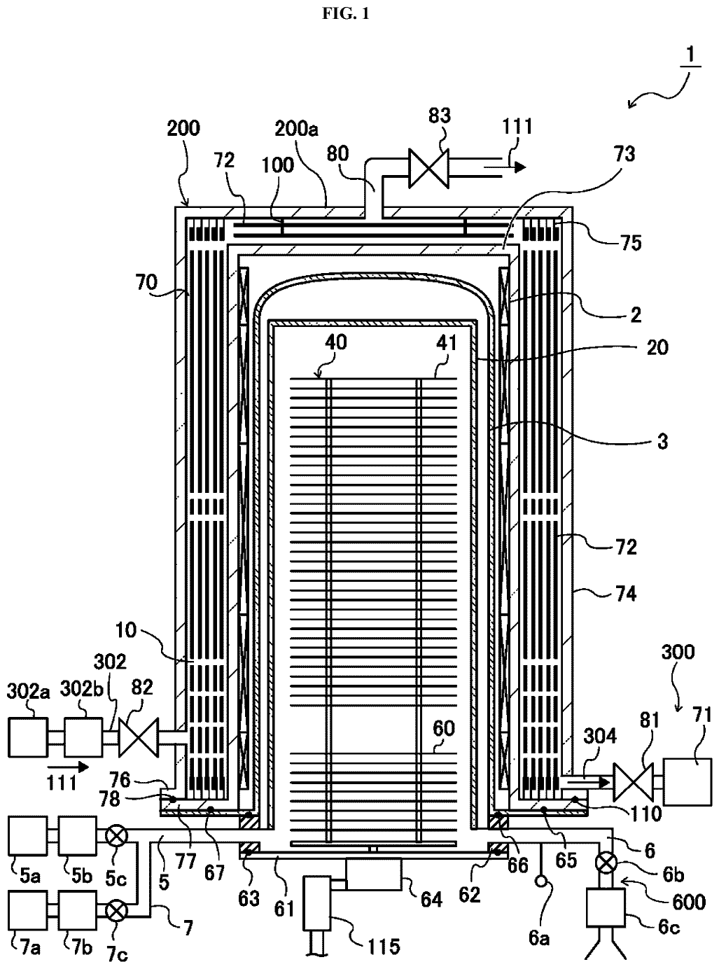

Hereinafter, one or more embodiments (also simply referred to as “embodiments”) of the technique of the present disclosure will be described in detail with reference to FIGS. 1 through 6. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

### (1) Configuration of Substrate Processing Apparatus

A configuration of a substrate processing apparatus 1 serving as a processing apparatus configured to process a substrate will be described with reference to FIG. 1.

The substrate processing apparatus 1 is constituted by a reaction tube 20, a boat 40 and a heater structure 200. The reaction tube 20 is of a cylindrical shape. An upper surface (upper portion) and a side surface (side portion) of the reaction tube 20 are integrally formed, and a lower surface (lower portion) of the reaction tube 20 is open. The boat 40 is accommodated (or stored) in the reaction tube 20 while a plurality of wafers 41 are loaded (charged) in the boat 40. Hereinafter, each of the wafers 41 may also be referred to as a “wafer 41”. The wafer 41 serves as the substrate. The heater structure 200 includes a heater 2 serving as a heat generator configured to heat an inside of the reaction tube 20 through the side portion thereof.

In the substrate processing apparatus 1 described above, a soaking tube (also referred to as a “heat equalizing tube”) 3 is provided at an inner side of the heater 2, and the reaction tube 20 is provided at an inner side of the soaking tube 3. The soaking tube 3 is made of a material whose thermal conductivity is high (for example, a silicon carbide (SiC) material), and is used to maintain a temperature uniformity in the reaction tube 20. The soaking tube 3 is of a cylindrical shape. An upper surface (upper portion) and a side surface (side portion) of the soaking tube 3 are integrally formed, and a lower surface (lower portion) of the soaking tube 3 is open. A flange is provided at a lower end of the soaking tube 3, and extends outward from the lower end of the soaking tube 3.

The heater 2 of a cylindrical shape is disposed between an inner heat insulating structure 73 and the soaking tube 3. The heater 2 is divided into a plurality of sub-heaters along an up-down direction (vertical direction).

A gas introduction pipe (gas introduction passage) 5 and an exhaust pipe (gas exhaust passage) 6 are provided at the lower portion of the reaction tube 20. An inner space of the gas introduction pipe 5 and an inner space of the exhaust pipe 6 are in communication with the inside of the reaction tube 20.

A gas supply source 5a, a mass flow controller (MFC) 5b serving as a flow rate controller (flow rate control structure) and a valve 5c are sequentially installed at the gas introduction pipe 5 in this order from an upstream side to a downstream side of the gas introduction pipe 5. An inert gas introduction pipe 7 is connected to a downstream side of the valve 5c of the gas introduction pipe 5. An inert gas supply source 7a, an MFC 7b and a valve 7c are sequentially installed at the inert gas introduction pipe 7 in this order from an upstream side to a downstream side of the inert gas introduction pipe 7.

A pressure sensor 6a serving as a pressure detector (pressure detection structure) configured to detect an inner pressure of the reaction tube 20, an APC (Automatic Pressure Controller) valve 6b and a vacuum pump 6c serving as a vacuum exhaust apparatus are sequentially installed at the exhaust pipe 6 in this order from an upstream side to a downstream side of the exhaust pipe 6. An exhauster (which is an exhaust structure or an exhaust system) 600 is constituted by the exhaust pipe 6, the pressure sensor 6a, the APC valve 6b and the vacuum pump 6c. The exhauster 600 is configured to vacuum-exhaust the reaction tube 20 such that the inner pressure of the reaction tube 20 reaches and is maintained at a predetermined pressure (degree of vacuum).

A lower end of the reaction tube 20 is open such that an entrance (also referred to as a “lower end opening”) is provided. The wafers 41 loaded in the boat 40 in a horizontal orientation are introduced (loaded) into or taken out (unloaded) from the reaction tube 20 through the lower end opening. That is, the boat 40 can be loaded into the reaction tube 20 from below by being elevated by an elevator (which is an elevating structure) 115, and can be unloaded from the reaction tube 20 by being lowered by the elevator 115.

Further, a flange 62 is provided around the lower end of the reaction tube 20. A gap (space) between the flange 62 and a furnace opening lid 61 is sealed by an airtight seal (for example, an O-ring) 63 when the furnace opening lid 61 is closed.

The soaking tube 3 and the reaction tube 20 are configured to be removable for performing an assembly work or a maintenance work (for example, a cleaning work). The soaking tube 3 is configured to be sealed to the inner heat insulating structure 73 by an airtight seal (for example, an O-ring) 65, and the reaction tube 20 is configured to be sealed to the soaking tube 3 by an airtight seal (for example, an O-ring) 66.

The boat 40 is provided with a rotator (which is a rotating structure) 64 configured to rotate the boat 40. Further, a plurality of heat insulating plates (for example, quartz plates) 60 are provided (loaded) at a lower portion of the boat 40. Hereinafter, each of the heat insulating plates 60 may also be referred to as a “heat insulating plate 60”. The heat insulating plates 60 are provided to prevent a non-uniform vertical temperature distribution of the wafers 41 above the heat insulating plates 60.

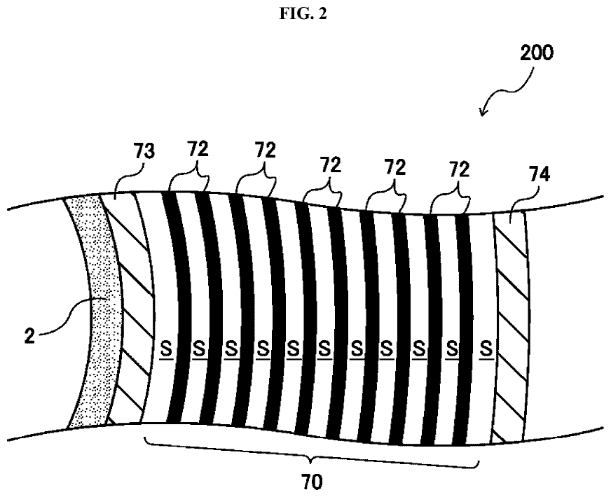

Subsequently, the heater structure 200 will be described in detail with reference to FIGS. 1 and 2.

The heater structure 200 includes the heater 2, the inner heat insulating structure 73 serving as a part of a heat insulating structure, an outer heat insulating structure 74 serving as a part of the heat insulating structure and a multilayer assembly 70 provided between the inner heat insulating structure 73 and the outer heat insulating structure 74. The heater structure 200 is configured as a multilayer structure constituted by the heater 2, the inner heat insulating structure 73, the multilayer assembly 70 and the outer heat insulating structure 74.

The inner heat insulating structure 73 is provided so as to cover peripheries of the upper surface and the side surface of the reaction tube 20. The outer heat insulating structure 74 is provided so as to cover peripheries of the upper surface and the side surface of the inner heat insulating structure 73. The heater 2 is attached to an inner side of the side surface of the inner heat insulating structure 73. The inner heat insulating structure 73 and the outer heat insulating structure 74 are configured to insulate a heat from the heater 2.

The multilayer assembly 70 includes a plurality of heat insulators 72 arranged along a direction extending outward from the inner heat insulating structure 73. Hereinafter, each of the heat insulators 72 may also be referred to as a “heat insulator 72”. A plurality of spaces S are provided between the heat insulators 72, respectively. Hereinafter, each of the spaces S may also be referred to as a “space S”. That is, the multilayer assembly 70 is provided outside the inner heat insulating structure 73, and is configured such that the spaces S are provided therein. In other words, the multilayer assembly 70 is configured such that the heat insulator 72 and the space S are arranged alternately.

That is, some of the heat insulators 72, provided with the space S therebetween, are provided between a side surface of the heater structure 200 and an outer circumferential side of the inner heat insulating structure 73, and are fastened and supported to the outer heat insulating structure 74 by a support structure 75. In addition, some of the heat insulators 72 are provided over an upper surface of the heater structure 200 with a gap therebetween in a heat insulating direction, and are fastened and supported to the outer heat insulating structure 74 by a support structure 100. Further, the heat insulator 72 is perforated with exhaust holes 10 in several locations.

In FIG. 1, the number of the heat insulators 72 on the side surface of the heater structure 200 is shown as five. However, as shown in FIG. 2, the number of the heat insulators 72 on the side surface of the heater structure 200 according to the present disclosure is preferably five or more, for example, ten. By setting the number of the heat insulators 72 in the multilayer assembly 70 to be ten, it is possible to effectively suppress the transfer of the heat inside the reaction tube 20 in a high temperature state. Further, by setting the number of the heat insulators 72 to be five or more, it is possible to further reduce an amount of the heat dissipated from a furnace (that is, the heat dissipated from the reaction tube 20). Thereby, it is possible to improve an energy saving efficiency of an apparatus (that is, the substrate processing apparatus 1).

In addition, the multilayer assembly 70 is also provided in a ceiling 200a of the heater structure 200 between the inner heat insulating structure 73 and the outer heat insulating structure 74. For example, two heat insulators are provided as the heat insulators 72. The two heat insulators are arranged substantially horizontally with a ceiling surface of the inner heat insulating structure 73 and a ceiling surface of the outer heat insulating structure 74. The ceiling 200a is provided above the reaction tube 20.

A width of the space S and a thickness of the heat insulator 72 are set such that a combined outer diameter of the inner heat insulating structure 73, the multilayer assembly 70 and the outer heat insulating structure 74 on the side surface of the heater structure 200 is substantially the same as an outer diameter of the ceiling 200a and such that the number of the heat insulators 72 is maximized. For example, when the thickness of the heat insulator 72 is 2.0 mm, it is preferable to set the number of the heat insulators 72 to be ten. By increasing the number of the heat insulators 72 provided in the multilayer assembly 70, it is possible to significantly reduce the amount of the heat dissipated from the furnace. Therefore, by preventing an excessive supply of the power to the heater 2, it is possible to improve the energy saving efficiency. The thickness of the heat insulator 72 is set to be a few millimeters in consideration of strength, for example, to a thickness of 1.0 mm or more and 3.0 mm or less.

A metal material or an alloy material may be used as the heat insulator 72. For example, a material with a thermal emissivity of 0.02 or more and 0.1 or less is used as the heat insulator 72. The thermal emissivity of 0.02 of the material used as the heat insulator 72 is a limit value at which the material with a melting point of 1,000° C. or more can be handled by a surface treatment. Further, when the melting point of the material is less than 1,000° C., the thermal emissivity of the material may be 0.02 or less. In other words, even when the thermal emissivity is about 0.01, the material can be handled by the surface treatment. In addition, by setting the thermal emissivity of the material to 0.1 or less by the surface treatment, it is possible to obtain a high thermal insulation performance. Further, by setting the melting point of the material used as the heat insulator 72 to be equal to or higher than a pre-set temperature in the reaction tube 20, it is possible to ensure a heat resistance.

Specifically, a material with a melting point of 1,000° C. or higher (such as gold (Au) and molybdenum (Mo)) is used as the heat insulator 72. By selecting such a material to configure the multilayer assembly 70, it is possible to significantly reduce the amount of the heat dissipated from the furnace. Therefore, by preventing the excessive supply of the power to the heater 2, it is possible to improve the energy saving efficiency.

The pre-set temperature in the reaction tube 20 is set appropriately depending on a process (such as a film forming process, an oxidation-diffusion process and an annealing process) performed in the reaction tube 20. For example, in a case of the film forming process, the pre-set temperature in the reaction tube 20 is set appropriately depending on a type of a film to be formed. The temperature of 1,000° C. mentioned above is merely an example of the pre-set temperature that can be used for almost the entire processes such as the film forming process, the oxidation-diffusion process and the annealing process. That is, a material (metal) for the heat insulator 72 can be selected depending on the process. For example, a material with a melting point equal to or higher than a temperature at which the material is processed in the reaction tube 20 can be selected.

Thicknesses of the inner heat insulating structure 73 and the outer insulating structure 74 are each configured to be thicker (larger) than the thickness of the heat insulator 72 and wider (larger) than the width of the space S formed between the heat insulators 72. By setting the inner heat insulating structure 73 thicker than the heat insulator 72, it is possible to easily hold (or support) the heater 2. Further, by setting the outer heat insulating structure 74 thicker than the heat insulator 72, it is possible to easily support the heat insulator 72. In addition, by lowering the thermal emissivity of the heat insulator 72 and by increasing the number of the heat insulators 72 by narrowing the width of the space S compared to the thickness of the inner heat insulating structure 73 and the thickness of the outer heat insulating structure 74, it is possible to reduce the amount of the heat dissipated from the furnace. In other words, it is possible to improve the thermal insulation performance of the heater structure 200.

The multilayer assembly 70 is provided by combining the inner heat insulating structure 73 of a cylindrical shape and the outer heat insulating structure 74 of a cylindrical shape in a state where a lower end of the inner heat insulating structure 73 and a lower end of the outer heat insulating structure 74 are tightly sealed together. An upper surface (upper portion) and a side surface (side portion) of the inner heat insulating structure 73 are integrally formed, and a lower surface (lower portion) of the inner heat insulating structure 73 is open. Further, an upper surface (upper portion) and a side surface (side portion) of the outer heat insulating structure 74 are integrally formed, and a lower surface (lower portion) of the outer heat insulating structure 74 is open. In other words, the side surface and the upper surface of the reaction tube 20 are covered with the multilayer structure constituted by the inner heat insulating structure 73 (which is provided with the heater 2), the multilayer assembly 70 and the outer heat insulating structure 74.

For example, the heat insulators 72 are configured such that the width of the space S can be changed by changing the number of the heat insulators 72 in the multilayer assembly 70 in accordance with the thermal emissivity and the thickness of the heat insulator 72.

For example, in a case of reducing the amount of the heat dissipated from the furnace (that is, in a case of improving the thermal insulation performance of the apparatus during a process such as a process of elevating a temperature of the furnace and a substrate processing), the width of the space S is set so as to maximize the number of the heat insulators 72 in the multilayer assembly 70. On the other hand, in a case of increasing the amount of the heat dissipated from the furnace, the width of the space S is set so as to reduce the number of the heat insulators 72 in the multilayer assembly 70.

A gas supply pipe (gas introduction passage) 302 serving as a gas supplier (which is a gas supply structure) through which a predetermined gas is supplied into the multilayer assembly 70 and a gas exhaust pipe (gas exhaust passage) 304 are provided at a lower portion of the heater structure 200. A gas exhaust pipe 80 is provided at an upper portion of the heater structure 200 approximately in a center of the ceiling 200a. Each of the gas supply pipe 302, the gas exhaust pipe 304 and the gas exhaust pipe 80 is located within the multilayer assembly 70 and is in communication with the space S provided between each of the heat insulators 72.

A gas supply source 302a, a mass flow controller (MFC) 302b serving as a flow rate controller (flow rate control structure) and a valve 82 are sequentially installed at the gas supply pipe 302 in this order from an upstream side to a downstream side of the gas supply pipe 302. The predetermined gas supplied from the gas supply source 302a is a gas whose thermal conductivity is higher than air. For example, a rare gas is used as the predetermined gas. For example, a gas such as helium (He) gas and hydrogen (H₂) gas may be used as the predetermined gas. The gas supply source 302a may be configured to allow a flow of not only a gaseous heat medium such as the gas exemplified above, but also a liquid heat medium.

A valve 83 is provided at the gas exhaust pipe 80. The gas exhaust pipe 80 is configured to exhaust a cooling gas supplied into the multilayer assembly 70 through the gas supply pipe 302 to an outside of the multilayer assembly 70.

An APC valve 81 and a vacuum pump 71 are sequentially installed at the gas exhaust pipe 304 in this order from an upstream side to a downstream side of the gas exhaust pipe 304. An exhauster 300 is constituted by the APC valve 81 and the vacuum pump 71. The exhauster (which is an exhaust structure or an exhaust system) 300 is configured to vacuum-exhaust an atmosphere in the space S provided between each of the heat insulators 72. More specifically, the exhauster 300 is configured to be capable of reducing a pressure of the space S provided between each of the heat insulators 72 to a vacuum level at which a heat dissipation due to a conductive heat is almost eliminated. That is, the vacuum pump 71 is connected to the multilayer assembly 70 via the APC valve 81, and the multilayer assembly 70 is configured to be capable of a vacuum heat insulation by opening the APC valve 81 and exhausting the atmosphere in the space S to the vacuum level with the vacuum pump 71.

The exhauster 300 is configured to be capable of reducing the pressure of the space S provided between each of the heat insulators 72 to less than 200 Pa. Thereby, for example, by setting the pressure of the space S between each of the heat insulators 72 to a vacuum level of less than 200 Pa, it is possible to suppress the heat dissipation due to the conductive heat. In other words, in a case of improving the thermal insulation performance of the apparatus during the process such as the process of elevating the temperature of the furnace and the substrate processing, the heat dissipation (heat escape) from the heater structure 200 can be limited to the radiant heat (also referred to as an “emissive heat”) alone. Thereby, it is possible to improve the energy saving efficiency.

In addition, with the APC valve 81 closed and the valves 82 and 83 open, the gas whose thermal conductivity is high is supplied through the gas supply pipe 302 to the space S provided between each of the heat insulators 72, and the gas circulated in the space S is exhausted to an outside of the apparatus through the gas exhaust pipe 80. In a manner described above, by supplying the gas whose thermal conductivity is high to the space S between each of the heat insulators 72, it is possible to increase the amount of the heat dissipated from the heater structure 200 (that is, an amount of the heat escape) by the heat dissipation due to the conductive heat in addition to the radiant heat, and it is also possible to significantly shorten a temperature lowering time of the furnace. It is also possible to fill the space S with the gas whose thermal conductivity is high without exhausting the gas to the outside of the apparatus through the gas exhaust pipe 80. When supplying the gas in a manner described above, the APC valve 81 is adjusted to adjust the pressure of the space S provided between each of the heat insulators 72 to 200 Pa or more.

In order to perform a cooling operation uniformly, a plurality of valves including the valve 82 may be provided in a circumferential direction. Further, in order to uniformly supply the predetermined gas 111 in the space S during the cooling operation, the exhaust holes 10 perforated at the heat insulator 72 may be configured to reduce a pressure loss in a lower portion of the heat insulator 72 compared to a pressure loss in an upper portion of the heat insulator 72. For example, a diameter of each of the exhaust holes 10 at the lower portion of the heat insulator 72 may be set to be greater than that of each of the exhaust holes 10 at the upper portion of the heat insulator 72, or the number of the exhaust holes 10 at the lower portion of the heat insulator 72 may be set to be greater than the number of the exhaust holes 10 at the upper portion of the heat insulator 72.

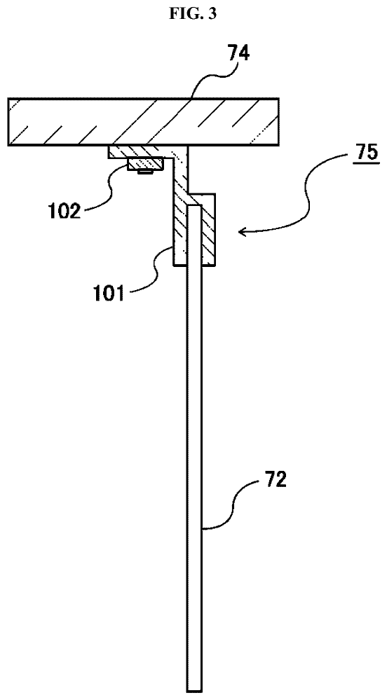

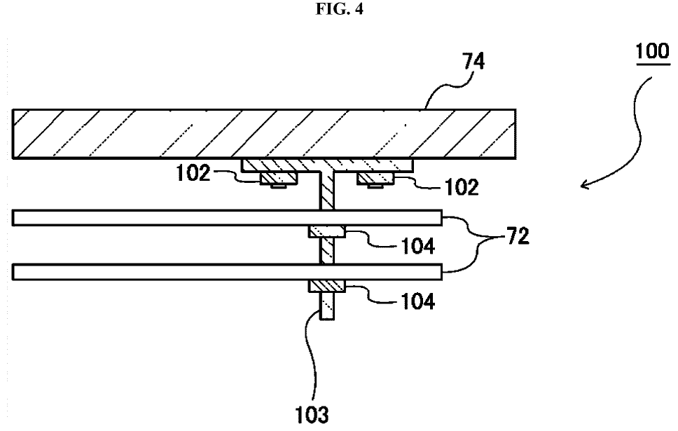

Subsequently, an installation of the heat insulator 72 will be described with reference to FIGS. 3 and 4. In FIGS. 3 and 4, an example of the installation of the heat insulator 72 is shown, but the installation of the heat insulator 72 is not limited thereto. As shown in FIG. 3, the heat insulator 72 is fitted into a groove (or recess) in a support bracket 101 made of a glass fiber material, for example. The support bracket 101 is fastened and supported to the outer heat insulating structure 74 by screws 102 made of the glass fiber material, for example. Such configuration of the support structure 75 is applied in a similar manner to above and below the heat insulator 72. Thereby, it is possible to support the heat insulator 72 in a thermally insulated manner by the outer heat insulating structure 74. Since a thermal conductivity of the support bracket 101 and a thermal conductivity of each screw 102 are low, it is possible to obtain a heat insulating effect.

As shown in FIG. 4, the support structure 100 is constituted by a support 103 and screws 102 and 104. For example, the support 103 is made of the glass fiber material, and is fastened and supported to the outer heat insulating structure 74 by the screws 102 described above. The support 103 is then passed through perforations in the heat insulator 72, and the outer heat insulating structure 74 is received by the screws 104 made of the glass fiber material described above, for example.

A flange 77 is provided at the lower end of the inner heat insulating structure 73, and extends outward from the lower end of the inner heat insulating structure 73. A flange 76 is provided at the lower end of the outer heat insulating structure 74, and extends outward from the lower end of the outer heat insulating structure 74. The inner heat insulating structure 73 and the outer heat insulating structure 74 are configured as a multiple structure in which the inner heat insulating structure 73 is inserted from below the outer heat insulating structure 74 to which the heat insulator 72 is fastened and supported. The inner heat insulating structure 73 and the outer heat insulating structure 74 are configured as a removable structure sealed by an airtight seal (for example, an O-ring) 78 provided between the flanges 76 and 77.

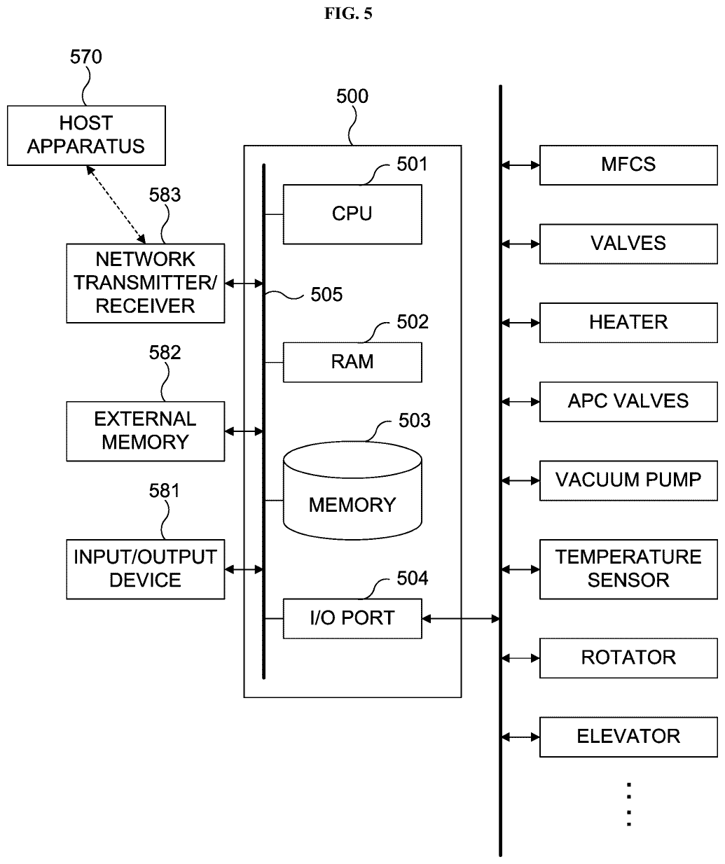

Subsequently, a controller serving as a control device (or a control structure) will be described with reference to FIG. 5. The substrate processing apparatus 1 includes a controller 500 configured to control operations of components constituting the substrate processing apparatus 1.

An outline of the controller 500 is shown in FIG. 5. For example, the controller 500 is constituted by a computer including a CPU (Central Processing Unit) 501, a RAM (Random Access Memory) 502, a memory 503 serving as a memory structure and an I/O (input/output) port 504. Each of the RAM 502, the memory 503 and the I/O port 504 is configured to be capable of exchanging data with the CPU 501 through an internal bus 505.

A network transmitter/receiver 583 connected to a host apparatus 570 via a network is provided at the controller 500. For example, the network transmitter/receiver 583 is capable of receiving data such as information regarding a processing history and a processing schedule of the wafer 41 from the host apparatus 570.

For example, the memory 503 may be embodied by a component such as a flash memory and a HDD (Hard Disk Drive). For example, a control program for controlling the operations of the substrate processing apparatus 1 or a process recipe in which information such as sequences and conditions of a method of manufacturing a semiconductor device (which is described later) is stored may be readably stored in the memory 503.

The process recipe is obtained by combining steps of the substrate processing described later such that the controller 500 can execute the steps to acquire a predetermined result, and functions as a program. Hereinafter, the process recipe and the control program may be collectively or individually referred to simply as a “program”. Thus, in the present specification, the term “program” may refer to the process recipe alone, may refer to the control program alone, or may refer to both of the process recipe and the control program. The RAM 502 serves as a memory area (work area) in which the program or the data read by the CPU 501 are temporarily stored.

The I/O port 504 is electrically connected to the components of the substrate processing apparatus 1 described above.

The CPU 501 is configured to read and execute the control program from the memory 503, and is configured to read the process recipe from the memory 503 in accordance with an instruction such as an operation command inputted from an input/output device 581. The CPU 501 is further configured to be capable of controlling the substrate processing apparatus 1 in accordance with contents of the process recipe read from the input/output device 581.

The controller 500 according to the present embodiments may be embodied by preparing an external memory 582 (for example, a magnetic disk such as a hard disk, an optical disk such as a DVD, a magneto-optical disk such as an MO, a semiconductor memory such as a USB memory) storing the program described above and by installing the program onto the computer by using the external memory 582. Further, a method of providing the program to the computer is not limited to the external memory 582. For example, the program may be directly provided to the computer by a communication interface such as the Internet and a dedicated line instead of the external memory 582. Further, the memory 503 and the external memory 582 may be embodied by a non-transitory computer-readable recording medium. Hereinafter, the memory 503 and the external memory 582 may be collectively or individually referred to as a “recording medium”. In the present specification, the term “recording medium” may refer to the memory 503 alone, may refer to the external memory 582 alone, or may refer to both of the memory 503 and the external memory 582.

Hereinafter, as a part of a manufacturing process of the semiconductor device (that is, the substrate processing described above), the film forming process of forming a film on the wafer 41 by using the substrate processing apparatus 1 described above will be described. In the following description, the controller 500 controls the operations of the components constituting the substrate processing apparatus 1.

The wafers 41 are transferred (or charged) into the boat 40 (wafer charging step). Thereafter, the boat 40 charged with the wafers 41 is elevated by the elevator 115 and loaded (transferred) into the reaction tube 20 (boat loading step). In such a state, the furnace opening lid 61 hermetically seals (closes) the lower end of the reaction tube 20 via the O-ring 63.

The inner pressure of the reaction tube 20 is controlled (or adjusted) to a predetermined pressure. In addition, the heater 2 heats the reaction tube 20 such that an inner temperature of the reaction tube 20 reaches and is maintained at a desired process temperature. More specifically, a state of the electric conduction to the heater 2 is feedback-controlled based on temperature information detected by a temperature sensor such that a desired temperature distribution of the inner temperature of the reaction tube 20 can be obtained. Then, by rotating the heat insulating plates 60 and the boat 40 by the rotator 64, the wafers 41 are rotated.

In such a state, the valves 82 and 83 are closed and the exhauster 300 is operated to exhaust the atmosphere in the space S provided between each of the heat insulators 72. Thereby, the atmosphere in the space S provided between each of the heat insulators 72 is set (or adjusted) to a vacuum state.

Subsequently, the valve 5c is opened, and a process gas (which is supplied from the gas supply source 5a and controlled to a desired flow rate by the MFC 5b) is introduced (or supplied) into the gas introduction pipe 5. The process gas introduced into the gas introduction pipe 5 is introduced into the reaction tube 20.

The process gas introduced into the reaction tube 20 comes into contact with surfaces of the wafers 41. Thereby, a process such as an oxidation process and a diffusion process is performed onto the wafers 41. When performing the process, since the boat 40 is rotated, the wafers 41 are also rotated. As a result, the process gas comes into contact with the entire surfaces of the wafers 41.

Furthermore, by exhausting the reaction tube 20 by the exhauster 600, the process gas introduced into the gas introduction pipe 5 is supplied into the reaction tube 20 at a predetermined flow rate. Thereby, for example, it is possible to quickly exhaust an out gas during a heat treatment process by the exhauster 600.

After a predetermined process time has elapsed, the valve 5c is closed, and the valve 7c is opened to supply an inert gas from the inert gas supply source 7a. Then, the inner atmosphere of the reaction tube 20 is replaced with the inert gas, a temperature of the wafer 41 is lowered (cooled down), and the inner pressure of the reaction tube 20 is returned to the normal pressure (atmospheric pressure).

In such a state, the APC valve 81 is closed, and the valves 82 and 83 are opened to supply the predetermined gas 111 into the space S provided between each of the heat insulators 72. Thereby, it is possible to rapidly cool the inside of the reaction tube 20.

Thereafter, the furnace opening lid 61 is lowered by the elevator 115 and the lower end of the reaction tube 20 is opened. Then, the boat 40 with the wafers (which are processed) 41 supported therein is unloaded (transferred) out of the reaction tube 20 through the lower end of the reaction tube 20 (boat unloading step). After the boat 40 is unloaded, the wafers (which are processed) 41 are discharged (transferred) from the boat 40 (wafer discharging step).

Therefore, by using the heater structure 200, it is possible to adjust the amount of the heat dissipated from the heater structure 200. In other words, by setting the pressure of the space S to a vacuum level when the heater structure 200 is operating (for example, when the temperature of the furnace is elevated), it is possible to improve the thermal insulation performance. Thereby, it is possible to achieve the energy saving efficiency. Further, when the temperature of the furnace is lowered (for example, when the heater structure 200 is stopped (that is, when the power of the heater structure 200 is turned off)), by supplying the gas whose thermal conductivity is high to the space S, it is possible to significantly shorten the temperature lowering time. In a manner described above, it is possible to efficiently perform a rapid temperature elevating operation and a rapid temperature lowering operation. In addition, a rapid cooling structure may be provided separately to supply the cooling gas between the soaking tube 3 and the inner heat insulating structure 73 when the temperature of the furnace is lowered.

According to the embodiments of the present disclosure, by setting the pressure of the space S provided between each of the heat insulators 72 to a vacuum level of several Pa, it is possible to suppress the heat dissipation due to the conductive heat. As a result, it is possible to suppress the heat dissipation (heat escape) from the heater 2 (that is, the heater structure 200).

That is, since the multilayer assembly 70 is configured such that the space S between each of the heat insulators 72 can be set to the vacuum state, by setting the pressure of the space S to the vacuum level during the process such as the process of elevating the temperature of the furnace and the substrate processing, it is possible to reduce the amount of the heat dissipated from the furnace, and it is also possible to improve the thermal insulation performance of the multilayer assembly 70. Thereby, it is possible to improve the energy saving efficiency.

In addition, according to the embodiments of the present disclosure, by supplying the gas whose thermal conductivity is high to the space S provided between each of the heat insulators 72, it is possible to increase the amount of the heat dissipated from the heater 2 (that is, the amount of the heat escape). Therefore, it is also possible to significantly shorten the temperature lowering time of the reaction tube 20.

That is, since the multilayer assembly 70 is configured such that the gas whose thermal conductivity is high can be supplied into the space S between each of the heat insulators 72, by supplying the gas whose thermal conductivity is high to the space S during the process such as the process of lowering the temperature of the furnace, it is possible to increase the amount of the heat dissipated from the furnace. Thereby, it is possible to perform the rapid temperature lowering of the furnace.

In addition, according to the embodiments of the present disclosure, it is possible to adjust the amount of the heat dissipated from the multilayer assembly 70 in accordance with the thermal conductivity of the space S and the thermal emissivity of the heat insulator 72, and it is also possible to adjust the amount of heat dissipated from the furnace. Thereby, it is possible to appropriately achieve the energy saving efficiency in accordance with the substrate processing.

In addition, according to the embodiments of the present disclosure, by using the material whose thermal emissivity is low as the heat insulator 72 and by increasing the number of the heat insulators 72 in the multilayer assembly 70, it is possible to significantly reduce the amount of the heat dissipation as compared with related arts. Therefore, by preventing the excessive supply of the power to the heater 2, it is possible to improve the energy saving efficiency as compared with the related arts.

### Modified Example

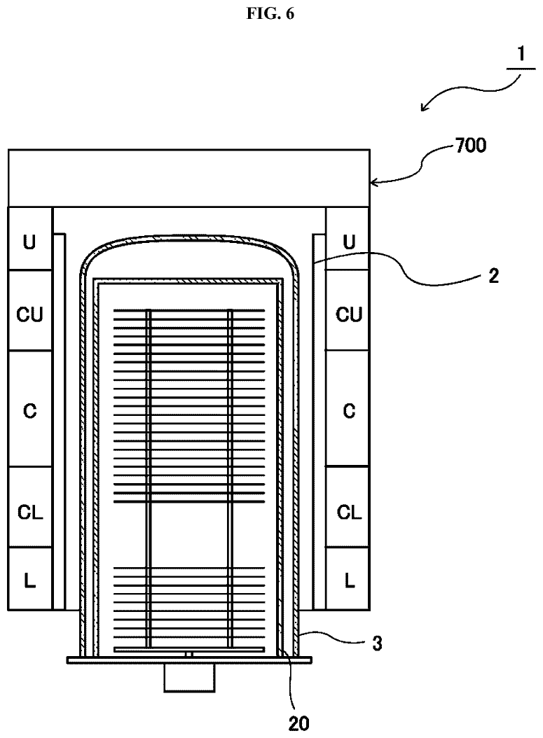

Subsequently, a modified example of the heater structure 200 of the embodiments mentioned above will be described in detail with reference to FIG. 6. In the following description of the modified example, only portions different from those of the embodiments mentioned above will be described in detail.

A heater structure 700 according to the present modified example is configured to be dividable into a plurality of regions. As shown in FIG. 6, the heater structure 700 can be divided into five control zones U, CU, C, CL and L from an upper end to a lower end of the side portion thereof. That is, the inner heat insulating structure 73, the multilayer assembly 70 and the outer heat insulating structure 74 in the side portion of the heater structure 700 are divided into the five control zones U, CU, C, CL and L, and each control zone is configured such that the multilayer assembly 70 related thereto can be set to the vacuum state or the gas whose thermal conductivity is high can be supplied into the multilayer assembly 70 related thereto. In addition, each control zone is provided with a pair of thermocouples such that each control zone can be controlled based on a temperature of each control zone. The exhauster 300 is configured to be capable of individually adjusting the pressure of the space S to 0 Pa to less than 200 Pa for each region.

That is, according to the present modified example, in addition to the effects according to the heater structure 200 described above, it is possible to control the heater structure 700 for each control zone. Thereby, it is possible to perform a temperature control individually and precisely.

### Other Embodiments of Present Disclosure

The embodiments mentioned above are described by way of an example in which the multilayer assembly 70 is provided with the heat insulators 72 and the space S is provided between each of the heat insulators 72. However, the technique of the present disclosure is not limited thereto. For example, the technique of the present disclosure may be applied when the multilayer assembly 70 is provided with the heat insulators 72 and a heat insulating material such as a heat insulating sheet is disposed (filled) in the space S provided between each of the heat insulators 72. Thereby, it is possible to further reduce the amount of the heat dissipated from the furnace. In other words, it is possible to further improve the thermal insulation performance of the heater structure 200.

Further, the embodiments mentioned above are described by way of an example in which the metal material (or the alloy material) such as gold (Au) and molybdenum (Mo) is used as the heat insulator 72. However, the technique of the present disclosure is not limited thereto. For example, the technique of the present disclosure may be applied when a material such as aluminum (Al), brass, chromium (Cr) and copper (Cu) is used as the heat insulator 72 depending on a surface treatment state such as a polishing state and an oxidation state and a process temperature related thereto.

Further, the embodiments mentioned above are described based on the heat insulators 72 on the side surface of the heater structure 200. However, the technique of the present disclosure is not limited thereto. For example, the technique of the present disclosure may be similarly applied to the heat insulators 72 on the upper surface (that is, the ceiling 200a) of the heater structure 200.

Further, the embodiments mentioned above are described by way of an example in which the film forming process is performed as the process performed by the substrate processing apparatus 1. However, the technique of the present disclosure is not limited thereto. For example, the technique of the present disclosure may be applied not only to a semiconductor manufacturing apparatus but also to an apparatus capable of processing a glass substrate such as an LCD apparatus. Further, for example, the film forming process may include a process such as a CVD process, a PVD process, a process of forming an oxide film, a nitride film or both of the oxide film and the nitride film and a process of forming a film containing a metal. Further, the technique of the present disclosure may also be applied to other process such as an annealing process, the oxidation process, a nitridation process and the diffusion process.

The technique of the present disclosure is described in detail by way of the embodiments and the modified example mentioned above. However, the technique of the present disclosure is not limited thereto. The technique of the present disclosure may be modified in various ways without departing from the scope thereof.

Hereinafter, examples of the embodiments of the present disclosure will be described.

### Example of Embodiments

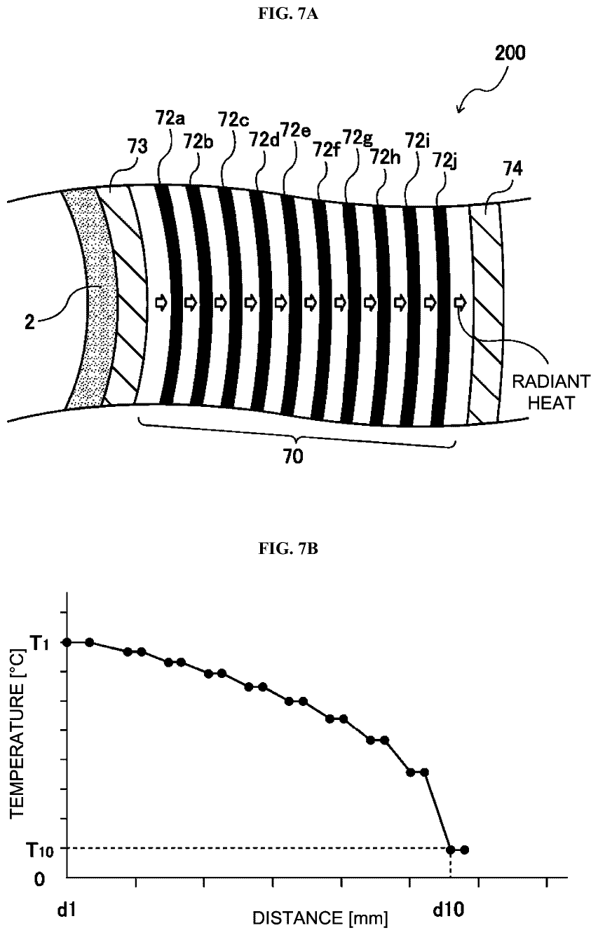

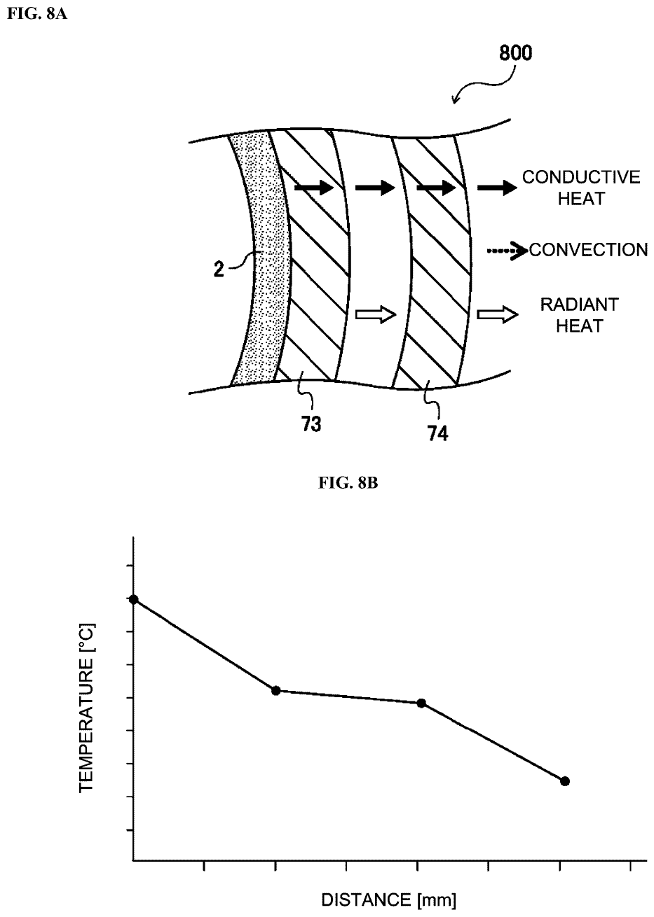

According to the present example, the substrate processing described above is performed using the substrate processing apparatus 1 provided with the heater structure 200 shown in FIG. 7A. According to a comparative example, the substrate processing described above is performed using a substrate processing apparatus provided with a heater structure 800 shown in FIG. 8A. FIG. 7B is a diagram schematically illustrating a relationship between a distance from a center of the reaction tube 20 and a temperature when the film forming process is performed using the substrate processing apparatus 1 according to the example of the embodiments of the present disclosure. FIG. 8B is a diagram schematically illustrating a relationship between a distance from a center of a reaction tube and a temperature when the film forming process is performed using the substrate processing apparatus according to the comparative example.

When a temperature of the heater 2 is T₁° C. and a temperature of a heat insulator 72a closest to the heater 2 is T₂° C., an amount of a heat Q1 transferred from the heater 2 to the heat insulator 72a due to the radiant heat can be expressed as follows:

$${Q}_{1} = A ε σ ( {T}_{1}^{4} - {T}_{2}^{4} ) . \qquad [ Equation 1 ]$$

In the equation 1, A is a surface area, ε is the thermal emissivity and σ is the Stefan-Boltzmann constant.

Similarly, when a temperature of a heat insulator 72b second closest to the heater 2 is T₃° C., a temperature of a heat insulator 72c third closest to the heater 2 is T₄° C., . . . , and a temperature of a heat insulator 72n n^{th} closest to the heater 2 is Tₙ₊₁° C., amounts of heats Q₂ through Qₙ transferred between each heat insulator can be expressed as follows:

$$[ Equation 2 ]$$

$${Q}_{{2}^{=}} A ε σ ( {T}_{2}^{4} - {T}_{3}^{4} ) ,$$

$${Q}_{{3}^{=}} A ε σ ( {T}_{3}^{4} - {T}_{4}^{4} ) , … , {Q}_{n} = A ε σ ( {T}_{n}^{4} - {T}_{∞}^{4} ) .$$

In the equation 2, n is an integer and T_{∞} is the ambient temperature.

When Q1 through Qn are summed up, the result can be expressed as follows:

$$Q 1 + Q 2 + Q 3 + … + {Q}_{n} = A ε σ ( {T}_{1}^{4} - {T}_{∞}^{4} ) . \qquad [ Equation 3 ]$$

In the equation 3, since Q1 through Qn are identical to one another, when each value of Q1 through Qn is set to Q, the result can be expressed as follows:

$$n Q = A ε σ ( {T}_{1}^{4} - {T}_{∞}^{4} ) \qquad [ Equation 4 ]$$

$$∴ Q = \frac{A ε σ ( {T}_{1}^{4} - {T}_{∞}^{4} )}{n}$$

In other words, when the number of the heat insulators is set to be n, the amount of the heat dissipated to the outside by the radiation from the heater 2 is reduced 1/n times as compared with a case where a single heat insulator alone is provided. Further, as the thermal emissivity of each of the heat insulators becomes lower and as the number of the heat insulators becomes larger, the heat dissipation is reduced.

According to the present example, as each of the heat insulators 72 (72a to 72j), a material whose thickness t is 2 mm, whose thermal emissivity ε is 0.1 and whose thermal conductivity, is 50 W/mK is used. Further, the width of the space S is set to 4 mm, the number of the heat insulators 72 is set to ten, the thermal conductivity λg of the space S in the vacuum state is set to 0 W/mK, and the thermal conductivity λg of the space S when helium gas is supplied to the space S is set to 0.25 W/mK.

Since the radiant heat between each of the heat insulators 72 may be considered alone, the amount of the heat dissipation Q in a case where the furnace is heated at a heater temperature of 800° C. (when the space S in the vacuum state) is calculated to be 1,280 W using the equations 1 to 3 described above.

In addition, the amount of the heat dissipation Q in a case where the heater temperature is reduced from 800° C. (when the helium gas is supplied to the space S) is calculated to be 9,603 W by summing up the amount of the heat dissipation due to the radiant heat, the amount of the heat dissipation due to the conductive heat in each of the heat insulators 72 and the amount of the heat dissipation due to the conductive heat between each of the heat insulators 72 (the conductive heat when the helium gas is supplied to the space S).

Therefore, it is confirmed that, by supplying the helium gas to the space S in the multilayer assembly 70, the amount of the heat dissipation when the temperature of the furnace is lowered can be increased to about 7.5 times the amount of the heat dissipation when the temperature of the furnace is elevated.

On the other hand, in a case where the furnace is heated at the heater temperature of 800° C. in the heater structure 800 of the comparative example, a temperature at an outer surface of the outer heat insulating structure 74, which is 620 mm away from the center of the heater structure 800, is 200° C., and the amount of the heat dissipation Q transferred from an inside of the inner heat insulating structure 73 to an outside of the outer heat insulating structure 74 is calculated to be 5,850 W.

That is, when the heater structure 200 of the present example is used, it is confirmed that, by setting the pressure of the space S to the vacuum level, the amount of the heat dissipation is reduced by approximately 80% as compared with a case where the heater structure 800 of the comparative example is used. Further, when the heater structure 200 of the present example is used, it is confirmed that, by supplying the helium gas to space S, the amount of the heat dissipation is increased 1.6 times as compared with the case where the heater structure 800 of the comparative example is used.

Therefore, by using the heater structure 200, it is possible to adjust the amount of the heat dissipated from the heater structure 200. Thereby, it is possible to obtain an energy saving effect, and it is also possible to improve the productivity. Further, by setting the pressure of the space S to the vacuum level at least when the temperature of the furnace is elevated, it is possible to improve the thermal insulation performance, and it is also possible to suppress a temperature lowering due to the heat escape from the heater structure 200. On the other hand, it is confirmed that, by supplying the gas whose thermal conductivity is high to space S when the temperature of the furnace is lowered, and thereby promoting the heat escape from the heater structure 200, it is possible to significantly shorten the temperature lowering time.

According to some embodiments of the present disclosure, it is possible to improve the energy saving efficiency of the apparatus.

What is claimed is:

1. A heater structure comprising:
a heat insulating structure provided with a heat generator configured to heat an inside of a reaction tube; and
a multilayer assembly located outside the heat insulating structure and provided with a plurality of spaces therein,
wherein the multilayer assembly comprises a plurality of heat insulators arranged along a direction extending outward from the heat insulating structure,
the plurality of spaces are provided between the plurality of heat insulators, respectively, and
an amount of a heat dissipated from the multilayer assembly is variable in accordance with a thermal conductivity of each of the spaces and a thermal emissivity of each of the heat insulators.

2. The heater structure of claim 1, wherein a width of each of the spaces is set such that number of the heat insulators at the multilayer assembly is maximized.

3. The heater structure of claim 1, wherein a material of each of the heat insulators is selected depending on a process performed in the reaction tube.

4. The heater structure of claim 1, wherein a material of each of the heat insulators is a metal material or an alloy material.

5. The heater structure of claim 1, wherein the thermal emissivity of each of the heat insulators is set to be 0.02 or more and 0.1 or less.

6. The heater structure of claim 3, wherein a melting point of each of the heat insulators is set to be equal to or higher than a temperature at which the process is performed in the reaction tube.

7. The heater structure of claim 1, further comprising
an exhauster configured to be capable of exhausting the plurality of spaces,
wherein the heater structure is configured such that a pressure of each of the spaces is reducible to a vacuum level at which a heat dissipation due to a conductive heat is substantially eliminated.

8. The heater structure of claim 7, wherein the exhauster is further configured to be capable of reducing the pressure of each of the spaces to less than 200 Pa.

9. The heater structure of claim 1, further comprising
a gas supplier configured to be capable of supplying a predetermined gas,
wherein the gas supplier is further configured to be capable of supplying the predetermined gas to each of the spaces provided between the plurality of heat insulators.

10. The heater structure of claim 9, wherein the predetermined gas comprises a gas whose thermal conductivity is higher than that of air.

11. The heater structure of claim 10, wherein the predetermined gas comprises a rare gas.

12. The heater structure of claim 10, further comprising
an exhauster configured to be capable of exhausting the plurality of spaces,
wherein the exhauster is further configured to be capable of adjusting a pressure of each of the spaces to 200 Pa or more.

13. The heater structure of claim 1, further comprising
a ceiling provided above the reaction tube,
wherein a width of each of the spaces and a thickness of each of the heat insulators are set such that a combined outer diameter of the heat insulating structure and the multilayer assembly is substantially same as an outer diameter of the ceiling.

14. The heater structure of claim 1, wherein a thickness of the heat insulating structure is set to be larger than a thickness of each of the heat insulators of the multilayer assembly and larger than a width of each of the spaces provided in the multilayer assembly.

15. The heater structure of claim 1, wherein the multilayer assembly is configured such that a heat insulating material is provided in each of the spaces.

16. The heater structure of claim 1, wherein the heat insulating structure and the multilayer assembly are configured to be dividable into a plurality of regions.

17. The heater structure of claim 16, further comprising
an exhauster configured to be capable of exhausting the plurality of spaces,
wherein the exhauster is further configured to be capable of adjusting a pressure of each of the spaces individually for each region to 1 Pa to less than 200 Pa.

18. A multilayer structure comprising:
a heat insulating structure provided with a heat generator configured to heat an inside of a reaction tube; and
a multilayer assembly located outside the heat insulating structure and provided with a plurality of spaces therein,
wherein the multilayer assembly comprises a plurality of heat insulators arranged along a direction extending outward from the heat insulating structure,
the plurality of spaces are provided between the plurality of heat insulators, respectively, and
an amount of a heat dissipated from the multilayer assembly is variable in accordance with a thermal conductivity of each of the spaces and a thermal emissivity of each of the heat insulators.

19. A processing apparatus comprising:
a heater structure comprising:
a heat insulating structure provided with a heat generator configured to heat an inside of a reaction tube; and
a multilayer assembly located outside the heat insulating structure and provided with a plurality of spaces therein,
wherein the multilayer assembly comprises a plurality of heat insulators arranged along a direction extending outward from the heat insulating structure,
the plurality of spaces are provided between the plurality of heat insulators, respectively, and
an amount of a heat dissipated from the multilayer assembly is variable in accordance with a thermal conductivity of each of the spaces and a thermal emissivity of each of the heat insulators.

20. A method of manufacturing a semiconductor device comprising
heating a substrate in the reaction tube with the heater structure of claim 1.
